(19) United States
(12) Patent Application Publication
(10) Pub. No.: US 2025/0120325 A1
(43) Pub. Date: Apr. 10, 2025

(54) SEMICONDUCTOR DEVICE AND MANUFACTURING METHOD OF SEMICONDUCTOR DEVICE

(71) Applicant: SK hynix Inc., Icheon (KR)

(72) Inventors: Seong Hyun KIM, Icheon-si (KR); Min Su KIM, Icheon-si (KR); Jae Sung PARK, Icheon-si (KR); Cheol Joon PARK, Icheon-si (KR)

(21) Appl. No.: 18/610,037

(22) Filed: Mar. 19, 2024

(30) Foreign Application Priority Data
Oct. 4, 2023 (KR) 10-2023-0131682

(51) Int. Cl. H10N 70/00; H10B 63/00

(52) U.S. Cl. CPC H10N 70/841; H10B 63/845; H10N 70/011

(57) ABSTRACT

A semiconductor device may include an access line, a variable resistance layer, an electrode located between the access line and the variable resistance layer, and a barrier structure located between the access line and the electrode and including an amorphous barrier. The barrier structure may further include a diffusion barrier, and the amorphous barrier has a resistivity higher than that of the diffusion barrier.

### CROSS-REFERENCE TO RELATED APPLICATION

This application claims priority under 35 U.S.C. § 119 to Korean Patent Application No. 10-2023-0131682 filed on Oct. 4, 2023, which is incorporated herein by reference in its entirety.

### BACKGROUND

### 1. Technical Field

Embodiments of the present disclosure relate to an electronic device, and more particularly, to a semiconductor device and a manufacturing method of the semiconductor device.

### 2. Related Art

Recently, in accordance with miniaturization, low power consumption, performance improvement, diversification, and the like, of electronic devices, semiconductor devices capable of storing information have been demanded in various electronic devices such as computers and portable communication devices. Accordingly, research into a semiconductor device capable of storing data using characteristics of switching between different resistance states depending on an applied voltage or current has been conducted. Examples of such a semiconductor device include a resistive random access memory (RRAM), a phase-change random access memory (PRAM), a ferroelectric random access memory (FRAM), a magnetic random access memory (MRAM), an E-fuse, and the like.

### SUMMARY

In an embodiment, a semiconductor device may include: an access line; a variable resistance layer; an electrode located between the access line and the variable resistance layer; and a barrier structure located between the access line and the electrode and including an amorphous barrier.

In an embodiment, a semiconductor device may include: a first access line; a second access line intersecting the first access line; a memory cell connected between the first access line and the second access line and including a variable resistance layer; a crystalline barrier located between the memory cell and the first access line; and an amorphous barrier located between the crystalline barrier and the memory cell.

In an embodiment, a manufacturing method of a semiconductor device may include: forming a first conductive layer; forming a barrier structure on the first conductive layer, the barrier structure including an amorphous barrier; forming a first electrode layer on the barrier structure; and forming a variable resistance layer on the first electrode layer.

### BRIEF DESCRIPTION OF THE DRAWINGS

FIG. 1 is a diagram illustrating the structure of a semiconductor device in accordance with an embodiment.

FIG. 2 is a diagram illustrating the structure of a semiconductor device in accordance with an embodiment.

FIG. 3 is a diagram illustrating the structure of a semiconductor device in accordance with an embodiment.

FIGS. 4A, 4B, 4C, and 4D are diagrams for describing the structure of a semiconductor device in accordance with an embodiment.

FIGS. 5A, 5B, 5C, and 5D are diagrams for describing the structure of a semiconductor device in accordance with an embodiment.

FIGS. 6A, 6B, 6C, and 6D are diagrams for describing a manufacturing method of a semiconductor device in accordance with an embodiment.

FIGS. 7A, 7B, 7C, and 7D are diagrams for describing a manufacturing method of a semiconductor device in accordance with an embodiment.

### DETAILED DESCRIPTION

Various embodiments are directed to a semiconductor device having a stable structure and improved characteristics and a manufacturing method of the semiconductor device.

By stacking memory cells in three dimensions, it is possible to improve the degree of integration of a semiconductor device. It is also possible to provide a semiconductor device having a stable structure and improved reliability.

As used herein, “at least one of . . . and” indicates a disjunctive list of each of items as well as possible combination(s). For example, “at least one of A and B” indicates “only A, or only B, or both A and B,” and “at least one of A, B, and C” indicates “only A, or only B, only C, or both A and B, or both A and C, or both B and C, or all of A and B and C,” and so on. Hereafter, embodiments in accordance with the technical spirit of the present disclosure will be described with reference to the accompanying drawings.

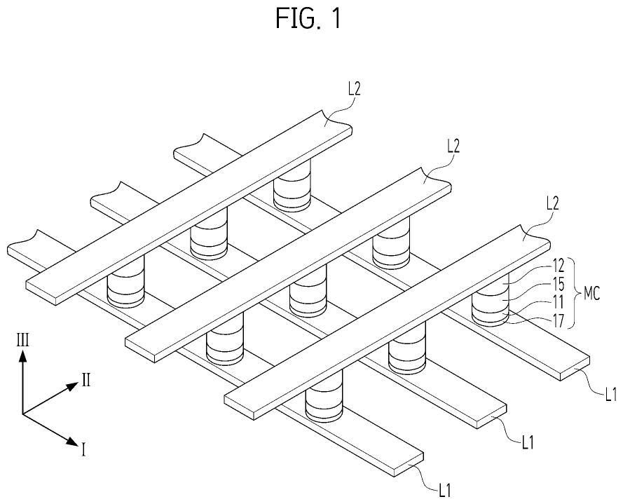

FIG. 1 is a diagram illustrating the structure of a semiconductor device in accordance with an embodiment.

Referring to FIG. 1, the semiconductor device in accordance with an embodiment may include at least one first access line L1, at least one second access line L2, and at least one memory cell MC.

The first access line L1 and the second access line L2 may intersect each other. The first access line L1 may extend in a first direction I. The second access line L2 may extend in a second direction II intersecting the first direction I. The first access line L1 and the second access line L2 may be stacked in a third direction III. The third direction III may be a direction substantially perpendicular to a plane defined by the first direction I and the second direction II. The first access line L1 and the second access line L2 may each be a word line or a bit line. As an example, the first access line L1 may be a word line, and the second access line L2 may be a bit line. Alternatively, the first access line L1 may be a bit line, and the second access line L2 may be a word line.

The memory cell MC may be located in a region where the first access line L1 and the second access line L2 intersect each other. The memory cells MC may be arranged in the first direction I and the second direction II. The memory cell MC may be connected between the first access line L1 and the second access line L2.

The memory cell MC may include a first electrode 11, a second electrode 12, and a variable resistance layer 15. For reference, it is also possible for the memory cell MC to include a switching layer instead of the variable resistance layer 15 or further include a switching layer in addition to the variable resistance layer 15. The variable resistance layer 15 may be located between the first electrode 11 and the second electrode 12. As an example, the first electrode 11, the variable resistance layer 15, and the second electrode 12 may be stacked in the third direction III. The first electrode 11 may be electrically connected to the first access line L1. The second electrode 12 may be electrically connected to the second access line L2.

A barrier structure 17 may be located at one or both of a first location between the memory cell MC and the first access line L1 and a second location between the memory cell MC and the second access line L2. The barrier structure 17 may include at least one of an amorphous barrier, a diffusion barrier, and a resistance barrier (e.g., a high-resistance barrier). The diffusion barrier may be located between the amorphous barrier and the high-resistance barrier. The amorphous barrier may be located between the diffusion barrier and the first electrode 11. The high-resistance barrier may be located between the diffusion barrier and the first access line L1. The diffusion barrier may be a crystalline barrier. The diffusion barrier may include at least one of metal nitride and graphene. The amorphous barrier may include at least one of metal oxynitride, graphene oxide, and reduced graphene oxide. The high-resistance barrier may include a tungsten silicon nitride layer.

In addition, although not illustrated in FIG. 1, the semiconductor device may further include circuits for controlling the first access lines L1 and the second access lines L2. As an example, the semiconductor device may include a first circuit such as a word line decoder and a word line driver. The first circuit may select a first access line L1 on which a program operation is to be performed according to a row address. The semiconductor device may include a second circuit such as a bit line decoder and a bit line driver. The second circuit may select a second access line L2 on which a program operation is to be performed according to a column address. During the program operation, a memory cell MC connected between the selected first access line L1 and the selected second access line L2 may be selected.

According to the structure described above, the memory cell MC may be protected through the barrier structure 17. Damage to the memory cell MC due to a spike current may be reduced through the high-resistance barrier, or the amorphous barrier, or both. In addition, diffusion of one or more elements of the high-resistance barrier into the memory cell MC may be significantly reduced through the diffusion barrier, or the amorphous barrier, or both.

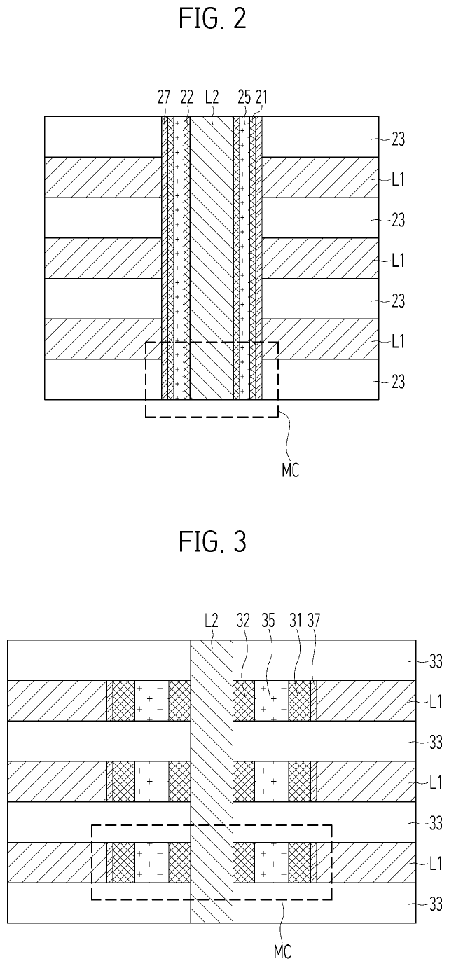

FIG. 2 is a diagram illustrating the structure of a semiconductor device in accordance with an embodiment. Hereinafter, the content overlapping with the previously described content may be omitted for the interest of brevity.

Referring to FIG. 2, the semiconductor device may include at least one first access line L1, at least one second access line L2, and at least one memory cell MC. The semiconductor device may further include at least one insulating layer 23.

The first access lines L1 may be stacked alternately with the insulating layers 23. The second access line L2 may penetrate through the first access lines L1. Alternatively, a vertical electrode may extend in a vertical direction through the first access lines L1 and the insulating layers 23, and the second access line L2 may be electrically connected to the vertical electrode. The first access line L1 and the second access line L2 may each be a word line or a bit line. As an example, the first access line L1 may be a word line, and the second access line L2 may be a bit line. Alternatively, the first access line L1 may be a bit line, and the second access line L2 may be a word line.

The memory cell MC may be located in a region where the first access line L1 and the second access line L2 intersect each other. As an example, the memory cells MC may be stacked in the vertical direction along the second access line L2. The memory cell MC may be connected between the first access line L1 and the second access line L2.

The memory cell MC may include a first electrode 21, a second electrode 22, and a variable resistance layer 25. For reference, it is also possible for the memory cell MC to include a switching layer instead of the variable resistance layer 25 or further include a switching layer in addition to the variable resistance layer 25. The variable resistance layer 25 may be located between the first electrode 21 and the second electrode 22. As an example, the second electrode 22 may surround a sidewall of the second access line L2. The variable resistance layer 25 may surround the second electrode 22. The first electrode 21 may surround the variable resistance layer 25. The first electrode 21 may be electrically connected to the first access line L1. The second electrode 22 may be electrically connected to the second access line L2.

A barrier structure 27 may be located at one or both of a first location between the memory cell MC and the first access line L1 and a second location between the memory cell MC and the second access line L2. The barrier structure 27 may include at least one of an amorphous barrier, a diffusion barrier, and a resistance barrier (e.g., a high-resistance barrier). The diffusion barrier may be located between the amorphous barrier and the high-resistance barrier. The amorphous barrier may be located between the diffusion barrier and the first electrode 21. The high-resistance barrier may be located between the diffusion barrier and the first access line L1. The diffusion barrier may be a crystalline barrier. The crystalline barrier may include at least one of metal nitride and graphene. The amorphous barrier may include at least one of metal oxynitride, graphene oxide, and reduced graphene oxide. The high-resistance barrier may include a tungsten silicon nitride layer.

According to the structure described above, it is possible to increase the degree of integration of a memory by stacking the memory cells MC. In addition, the memory cell MC may be protected through the barrier structure 27. Damage to the memory cell MC due to a spike current may be reduced through the high-resistance barrier and the amorphous barrier. In an embodiment, each of the high-resistance barrier and the amorphous barrier may have a relatively high electrical resistivity to significantly reduce a magnitude of a spike current. In addition, diffusion of an element of the high-resistance barrier into the memory cell MC may be reduced through the diffusion barrier and the amorphous barrier.

FIG. 3 is a diagram illustrating the structure of a semiconductor device in accordance with an embodiment. Hereinafter, the content overlapping with the previously described content may be omitted for the interest of brevity.

Referring to FIG. 3, the semiconductor device may include at least one first access line L1, at least one second access line L2, and at least one memory cell MC. The semiconductor device may further include at least one insulating layer 33.

The first access lines L1 may be stacked alternately with the insulating layers 33. The second access line L2 may penetrate through the first access lines L1. The first access line L1 and the second access line L2 may each be a word line or a bit line.

The memory cell MC may be located in a region where the first access line L1 and the second access line L2 intersect each other. The memory cell MC may include a first electrode 31, a second electrode 32, and a variable resistance layer 35. For reference, it is also possible for the memory cell MC to include a switching layer instead of the variable resistance layer 35 or further include a switching layer in addition to the variable resistance layer 35. The variable resistance layer 35 may be located between the first electrode 31 and the second electrode 32. The second electrode 32, the variable resistance layer 35, and the first electrode 31 may be located between the stacked insulating layers 33. The variable resistance layers 35 of the stacked memory cells MC may be separated from each other. The first electrode 31 may be electrically connected to the first access line L1. The second electrode 32 may be electrically connected to the second access line L2.

A barrier structure 37 may be located at one or both of a first location between the memory cell MC and the first access line L1 and a second location between the memory cell MC and the second access line L2. The barrier structure 37 may include at least one of an amorphous barrier, a diffusion barrier, and a high-resistance barrier. The diffusion barrier may be located between the amorphous barrier and the high-resistance barrier. The amorphous barrier may be located between the diffusion barrier and the first electrode 31. The high-resistance barrier may be located between the diffusion barrier and the first access line L1. The diffusion barrier may be a crystalline barrier. The crystalline barrier may include at least one of metal nitride and graphene. The amorphous barrier may include at least one of metal oxynitride, graphene oxide, and reduced graphene oxide. The high-resistance barrier may include a tungsten silicon nitride layer.

According to the structure described above, it is possible to increase the degree of integration of a memory by stacking the memory cells MC. It is possible to improve data retention characteristics by separating the variable resistance layers 35 of the memory cells MC from each other. In addition, the memory cell MC may be protected through the barrier structure 37. Damage to the memory cell MC due to a spike current may be reduced through the high-resistance barrier and the amorphous barrier. In addition, diffusion of an element of the high-resistance barrier into the memory cell MC may be reduced through the diffusion barrier and the amorphous barrier.

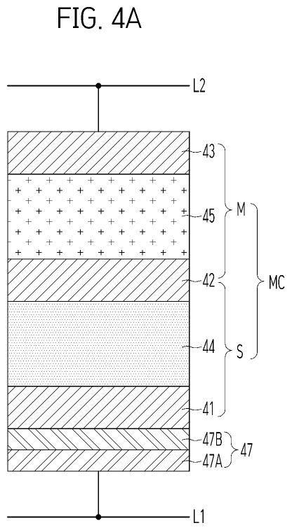

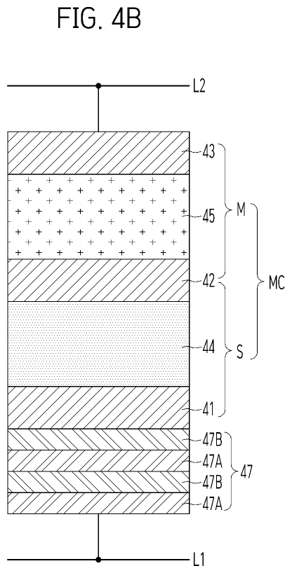

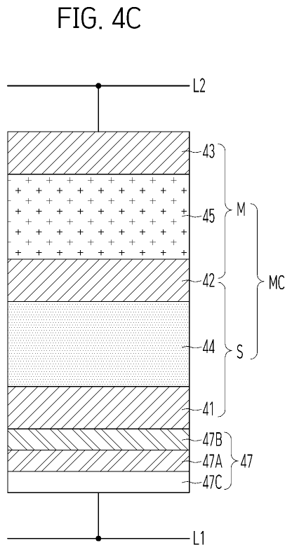

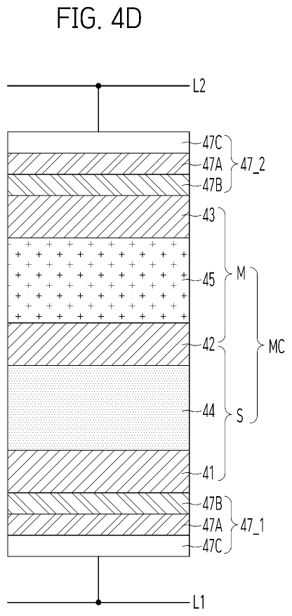

FIGS. 4A to 4D are diagrams for describing the structure of a semiconductor device in accordance with an embodiment. Hereinafter, the content overlapping with the previously described content may be omitted for the interest of brevity.

Referring to FIGS. 4A to 4D, the semiconductor device may include a first access line L1, a second access line L2, and a memory cell MC. The memory cell MC may be connected between the first access line L1 and the second access line L2.

The memory cell MC may include a selection element S and a memory element M. The selection element S may adjust a flow of current depending on the magnitude of an applied voltage or current. The memory cell MC may be selected depending on the turn-on or turn-off of the selection element S. The selection element S may include a first electrode 41, a switching layer 44, and a second electrode 42. The switching layer 44 may be located between the first electrode 41 and the second electrode 42. The switching layer 44 may maintain a specific phase such as amorphous phase during an operation of the memory cell MC. As an example, the switching layer 44 may include a chalcogenide material. The first electrode 41 may be located between the switching layer 44 and the first access line L1, and may be electrically connected to the first access line L1.

The memory element M may include the second electrode 42, a variable resistance layer 45, and a third electrode 43. The variable resistance layer 45 may be located between the second electrode 42 and the third electrode 43. The selection element S and the memory element M may share the second electrode 42 with each other. The third electrode 43 of the memory element M may be electrically connected to the second access line L2.

The variable resistance layer 45 may have characteristics of reversibly transitioning between different resistance states depending on a voltage or a current applied to the memory element M. As an example, when the variable resistance layer 45 has a low resistance state, data ‘1’ may be stored, and when the variable resistance layer 45 has a high resistance state, data ‘0’ may be stored.

As an example, the variable resistance layer 45 may include a resistive material. An electrical path is generated or disappears in the variable resistance layer 45, such that data may be stored. As an example, the variable resistance layer 45 may include transition metal oxide or include metal oxide such as a perovskite-based material.

As an example, the variable resistance layer 45 may have a magnetic tunnel junction (MTJ) structure including a magnetization pinned layer, a tunnel barrier layer, and a magnetization free layer. The data may be stored according to a change in magnetization direction of the magnetization free layer with respect to a magnetization direction of the magnetization pinned layer. As an example, the magnetization pinned layer and the magnetization free layer may each include a magnetic material, and the tunnel barrier layer may include metal oxide.

As an example, the variable resistance layer 45 may include a phase change material or include a chalcogenide-based material. The variable resistance layer 45 may change its phase according to a program operation. As an example, the variable resistance layer 45 may have a low-resistance crystalline state through a set operation. As an example, the variable resistance layer 45 may have a high-resistance amorphous state through a reset operation. Accordingly, the data may be stored in the memory cell using a difference in resistance depending on a phase of the variable resistance layer 45.

As an example, the variable resistance layer 45 may include a variable resistance material whose resistance changes without a phase change or include a chalcogenide-based material. The variable resistance layer 45 may maintain its phase after the program operation. As an example, the variable resistance layer 45 may have an amorphous state, and may maintain the amorphous state without changing to a crystalline state after the program operation. A threshold voltage of the memory cell may be changed depending on a program voltage applied to the memory cell, and the memory cell may be programmed to at least two states. As an example, the memory cell may be programmed to a set state or a reset state using program voltages having different polarities. Accordingly, the data may be stored in the memory cell using a difference in the threshold voltage of the memory cell.

The first electrode 41, the second electrode 42, and the third electrode 43 may each include a conductive material such as polysilicon or metal. As an example, the first electrode 41, the second electrode 42, and the third electrode 43 may each include at least one of polysilicon, tungsten (W), tungsten nitride (WNₓ), tungsten silicide (WSiₓ), titanium (Ti), titanium nitride (TiNₓ), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbonitride (SiCN), copper (Cu), zinc (Zn), nickel (Ni), cobalt (Co), lead (Pb), platinum (Pt), molybdenum (Mo), and ruthenium (Ru). The first electrode 41, the second electrode 42, and the third electrode 43 may include the same material or include different materials. As an example, at least one of the first electrode 41, the second electrode 42, and the third electrode 43 may include a carbon layer.

The semiconductor device may further include a barrier structure 47 located at one of both of a first location between the first access line L1 and the memory cell MC and a second location between the second access line L2 and the memory cell MC. The barrier structure may include at least one of a diffusion barrier 47A, an amorphous barrier 47B, and a high-resistance barrier 47C.

Referring to FIG. 4A, the barrier structure 47 may include a diffusion barrier 47A and an amorphous barrier 47B. As an example, the amorphous barrier 47B may be located on the diffusion barrier 47A. Here, locations of the diffusion barrier 47A and the amorphous barrier 47B may be changed. As an example, the diffusion barrier 47A may be located on the amorphous barrier 47B.

The diffusion barrier 47A may be located between the first electrode 41 and the first access line L1. Diffusion of metal included in the first access line L1 or the like into the memory cell MC may be reduced by the diffusion barrier 47A. The diffusion barrier 47A may have a thickness of several nanometers. As an example, the diffusion barrier 47A may have a thickness of 10 to 70 Å or have a thickness of 30 to 50 Å. The diffusion barrier 47A may be a crystalline barrier. As an example, the diffusion barrier 47A may have a polycrystalline structure.

A bonding distance between elements included in the diffusion barrier 47A may be smaller than a diameter of an element whose diffusion is to be reduced. As an example, the diffusion barrier 47A may include at least one of metal nitride and graphene. The metal nitride may include at least one of titanium, tungsten, nickel, and molybdenum. A bonding distance between elements of the metal nitride may be smaller than a diameter of tungsten and/or silicon. The graphene may have a two-dimensional plate-like structure, and a lattice distance of carbon-carbon may be smaller than the diameter of tungsten and/or silicon.

The amorphous barrier 47B may be located between the first electrode 41 and the first access line L1, and may be located between the diffusion barrier 47A and the first electrode 41. The amorphous barrier 47B may have a different crystal structure from the diffusion barrier 47A. The amorphous barrier 47B may have a higher resistivity than the diffusion barrier 47A.

As an example, the diffusion barrier 47A may have a crystalline structure, and the amorphous barrier 47B may have an amorphous structure. Because the amorphous barrier 47B does not have a grain structure unlike the diffusion barrier 47A, even though an element (e.g., metal) is diffused through a grain boundary of the diffusion barrier 47A, the diffusion of the metal may be reduced through the amorphous barrier 47B compared to the diffusion of the metal through the diffusion barrier 47A. A change in composition of the variable resistance layer 45 due to the diffusion of the metal into the memory cell MC may be reduced, and the memory cell MC may be protected.

The diffusion barrier 47A may include metal nitride, and the amorphous barrier 47B may include metal oxynitride. A metal oxynitride layer may be formed by oxidizing a surface of a metal nitride layer. The diffusion barrier 47A may include graphene, and the amorphous barrier 47B may include graphene oxide. The diffusion barrier 47A may include graphene, and the amorphous barrier 47B may include reduced graphene oxide. The amorphous barrier 47B may have a smaller thickness than the diffusion barrier 47A. For example, the thickness of the amorphous barrier 47B may be smaller than 30% of the thickness of the diffusion barrier 47A.

The graphene oxide and the reduced graphene oxide have a carbon ring structure, and may thus serve as a diffusion barrier. In addition, the graphene oxide and the reduced graphene oxide include a functional group bonded to a carbon ring, and may thus be used as a seed of the first electrode 41 or increase adhesive strength of the first electrode 41. The reduced graphene oxide may have a smaller interlayer distance than the graphene oxide and have smaller band gap energy than the graphene oxide. Accordingly, the reduced graphene oxide may have higher electrical conductivity and/or thermal conductivity than the graphene oxide.

Referring to FIG. 4B, the barrier structure 47 may include at a plurality of diffusion barriers 47A and a plurality of amorphous barriers 47B. The barrier structure 47 may include a plurality of diffusion barriers 47A and a plurality of amorphous barrier 47B that are alternately stacked. As an example, the barrier structure 47 may include metal nitride layers and metal oxynitride layers that are alternately stacked. The barrier structure 47 may include graphene layers and graphene oxide layers that alternately stacked. The barrier structure 47 may include graphene layers and reduced graphene oxide layers that alternately stacked.

For reference, it is also possible for two of the diffusion barriers 47A, the amorphous barriers 47B, and the high-resistance barriers 47C to be alternately stacked. As an example, the barrier structure 47 may include the amorphous barriers 47B and the high-resistance barriers 47C that are alternately stacked. The barrier structure 47 may include the diffusion barriers 47A and the high-resistance barriers 47C that are alternately stacked. The barrier structure 47 may include the amorphous barriers 47B and the high-resistance barriers 47C that are alternately stacked and the diffusion barriers 47A and the high-resistance barriers 47C that are alternately stacked.

Referring to FIG. 4C, the barrier structure 47 may include a diffusion barrier 47A, an amorphous barrier 47B, and a high-resistance barrier 47C. The high-resistance barrier 47C may be located between the amorphous barrier 47B and the first access line L1. The high-resistance barrier 47C may be located between the diffusion barrier 47A and the first access line L1. In some embodiments, it is also possible for a plurality of diffusion barriers 47A and a plurality of amorphous barriers 47B to be alternately stacked on the high-resistance barrier 47C.

The high-resistance barrier 47C may have a higher resistivity than the amorphous barrier 47B. The high-resistance barrier 47C may reduce transmission of a spike current generated during an operation to the memory cell MC. The high-resistance barrier 47C may include metal. As an example, the high-resistance barrier 47C may include a tungsten silicon nitride layer.

When a program operation is repeatedly performed, the high-resistance barrier 47C may deteriorate, and an element included in the high-resistance barrier 47C may be diffused into the memory cell MC. In such a case, at least one of the diffusion barrier 47A and the amorphous barrier 47B may reduce the diffusion of the element included in the high-resistance barrier 47C into the memory cell MC. As an example, at least one of the diffusion barrier 47A and the amorphous barrier 47B may reduce diffusion of at least one of tungsten and silicon included in the high-resistance barrier 47C into the memory cell MC.

Referring to FIG. 4D, the semiconductor device may include a 5 first barrier structure 47_1 and a second barrier structure 47_2. The first barrier structure 471 may include at least one of a diffusion barrier 47A, an amorphous barrier 47B, and a high-resistance barrier 47C. The second barrier structure 47_2 may include at least one of a diffusion barrier 47A, an amorphous barrier 47B, and a high-resistance barrier 47C. As an example, each of the first barrier structure 47_1 and the second barrier structure 47_2 may have the structures described above with reference to FIGS. 4A to 4C or have combinations thereof.

The first barrier structure 47_1 and the second barrier structure 472 may have a symmetrical shape or an asymmetrical shape with respect to the memory cell MC. As an example, in the first barrier structure 47_1, the diffusion barrier 47A may be located on the high-resistance barrier 47C, and the amorphous barrier 47B may be located on the diffusion barrier 47A. In the second barrier structure 47_2, the diffusion barrier 47A may be located on the amorphous barrier 47B, and the high-resistance barrier 47C may be located on the diffusion barrier 47A. For example, in the embodiment of FIG. 4D, the layers in the first barrier structure 47_1 are stacked in the order of the high-resistance barrier 47C, the diffusion barrier 47A, and the amorphous barrier 47B, and the second barrier structure 47_2 are stacked in the order of the amorphous barrier 47B, the diffusion barrier 47A, and the high-resistance barrier 47C. As a result, in the embodiment of FIG. 4D, the first barrier structure 47_1 and the second barrier structure 47_2 have a substantially symmetrical structure with respect to the memory cell MC.

According to the structure described above, the barrier structure 47 may include at least one of the diffusion barrier 47A, the amorphous barrier 47B, and the high-resistance barrier 47C. Diffusion of an element included in the first access line L1 and/or the high-resistance barrier 47C into the memory cell MC may be reduced through the diffusion barrier 47A. The transmission of the spike current to the memory cell MC may be reduced through the high-resistance barrier 47C.

The amorphous barrier 47B may serve as both a diffusion barrier and a high-resistance barrier. The diffusion barrier 47A and the amorphous barrier 47B may reduce the diffusion of the element included in the high-resistance barrier 47C into the memory cell MC. The high-resistance barrier 47C and the amorphous barrier 47B may reduce the transmission of the spike current to the memory cell MC.

Accordingly, it is possible to protect the memory cell MC by locating the barrier structure 47 at one or both of a first location between the memory cell MC and the first access line L1 and a second location between the memory cell MC and the second access line L2.

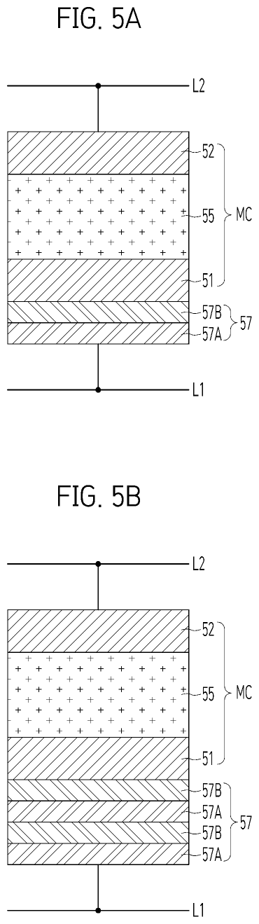

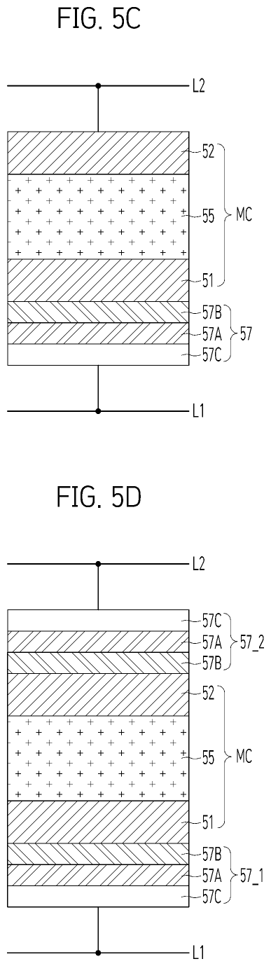

FIGS. 5A to 5D are diagrams for describing the structure of a semiconductor device in accordance with an embodiment. Hereinafter, the content overlapping with the previously described content may be omitted for the interest of brevity.

Referring to FIGS. 5A to 5D, the semiconductor device may include a first access line L1, a second access line L2, and a memory cell MC. The memory cell MC may be connected between the first access line L1 and the second access line L2.

The memory cell MC may be a storage element while being a selection element. As an example, the memory cell MC may include a first electrode 51, a second electrode 52, and a variable resistance layer 55 located between the first electrode 51 and the second electrode 52. The variable resistance layer 55 may be a switching layer of the selection element while being a memory layer of a memory element. The variable resistance layer 55 may have an amorphous state, and may maintain the amorphous state without changing to a crystalline state after a program operation. Depending on a program voltage applied to the memory cell, a composition of the variable resistance layer 55 may be changed and a threshold voltage of the memory cell may be changed. Accordingly, data may be stored in the memory cell using a difference in the threshold voltage of the memory cell.

Referring to FIG. 5A, the barrier structure 57 may include a diffusion barrier 57A and an amorphous barrier 57B. The diffusion barrier 57A may be a crystalline barrier. The amorphous barrier 57B may be formed by oxidizing the diffusion barrier 57A. The diffusion barrier 57A may include metal nitride, and the amorphous barrier 57B may include metal oxynitride. The diffusion barrier 57A may include graphene, and the amorphous barrier 57B may include graphene oxide. The diffusion barrier 57A may include graphene, and the amorphous barrier 57B may include reduced graphene oxide.

Referring to FIG. 5B, the barrier structure 57 may include diffusion barriers 57A and amorphous barriers 57B that are alternately stacked. As an example, the barrier structure 57 may include metal nitride layers and metal oxynitride layers that are alternately stacked. The barrier structure 57 may include graphene layers and graphene oxide layers that alternately stacked. The barrier structure 57 may include graphene layers and reduced graphene oxide layers that alternately stacked.

Referring to FIG. 5C, the barrier structure 57 may include a diffusion barrier 57A, an amorphous barrier 57B, and a high-resistance barrier 57C. The diffusion barrier 57A may be a crystalline barrier. The high-resistance barrier 57C may be located between the memory cell MC and the first access line L1. The diffusion barrier 57A (e.g., crystalline barrier) may be located between the high-resistance barrier 57C and the memory cell MC. The amorphous barrier 57B may be located between the crystalline barrier 57A and the memory cell MC.

The amorphous barrier 57B may have a higher resistivity than the crystalline barrier 57A. The high-resistance barrier 57C may have a higher resistivity than the amorphous barrier 57B and the crystalline barrier 57A. The crystalline barrier 57A may include at least one of metal nitride and graphene. The amorphous barrier 57B may include at least one of metal oxynitride, graphene oxide, and reduced graphene oxide. The high-resistance barrier 57C may include a tungsten silicon nitride layer.

Referring to FIG. 5D, the semiconductor device may include a first barrier structure 57_1 and a second barrier structure 57_2. The first barrier structure 571 may include at least one of a diffusion barrier 57A, an amorphous barrier 57B, and a high-resistance barrier 57C. The second barrier structure 57_2 may include at least one of a diffusion barrier 57A, an amorphous barrier 57B, and a high-resistance barrier 57C.

According to the structure described above, the variable resistance layer 55 of the memory cell MC may serve as both the memory element and the selection element. The barrier structure 57 may include at least one of the diffusion barrier 57A, the amorphous barrier 57B, and the high-resistance barrier 57C. Diffusion of an element in a peripheral layer (e.g., the first line L1, the second line L2, and/or the high-resistance layer 57C) into the memory cell MC may be reduced through the barrier structure 57. In addition, transmission of a spike current to the memory cell MC may be reduced through the barrier structure 57.

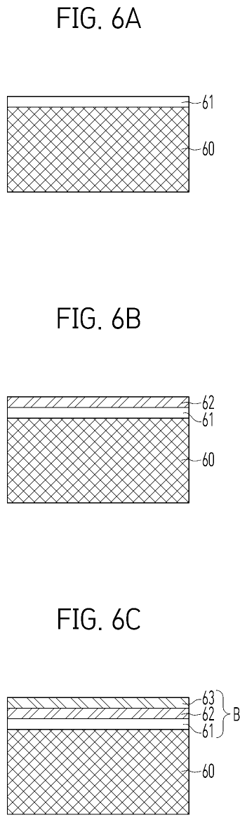

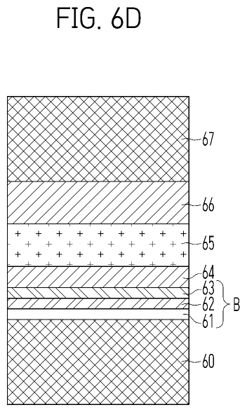

FIGS. 6A to 6D are diagrams for describing a manufacturing method of a semiconductor device in accordance with an embodiment. Hereinafter, the content overlapping with the previously described content may be omitted for the interest of brevity.

Referring to FIG. 6A, a first conductive layer 60 may be formed. The first conductive layer 60 may be used to form an access line or an electrode. The access line may be a word line or a bit line.

Subsequently, a barrier structure including an amorphous barrier may be formed on the first conductive layer 60. First, a first barrier layer 61 may be formed on the first conductive layer 60. The first barrier layer 61 may be a high-resistance barrier. The first barrier layer 61 may be a metal-containing layer. As an example, the first barrier layer 61 may include a tungsten silicon nitride layer.

Referring to FIG. 6B, a second barrier layer 62 may be formed on the first barrier layer 61. For reference, it is also possible to omit the first barrier layer 61 and form the second barrier layer 62 on the first conductive layer 60. Here, the second barrier layer 62 may be a diffusion barrier. As an example, the second barrier layer 62 may include a metal nitride layer. The second barrier layer 62 may include at least one of titanium, tungsten, nickel, and molybdenum. As an example, the second barrier layer 62 may include graphene. The graphene may be formed by a deposition method such as chemical vapor deposition (CVD). The second barrier layer 62 may include single-layer graphene or multilayer graphene. A thickness of the single-layer graphene may be 2 to 5 Å, and may be about 3 Å.

Referring to FIG. 6C, a third barrier layer 63 may be formed on the second barrier layer 62. For reference, it is also possible to omit at least one of the first barrier layer 61 and the second barrier layer 62 and form the third barrier layer 63. Here, the third barrier layer 63 may be an amorphous barrier. The third barrier layer 63 may have a higher resistivity than the second barrier layer 62, and the first barrier layer 61 may have a higher resistivity than the third barrier layer 63.

As an example, the third barrier layer 63 may be formed by oxidizing a surface of the second barrier layer 62. The second barrier layer 62 may be a metal nitride layer, and the third barrier layer 63 may be a metal oxynitride layer formed by oxidizing the metal nitride layer. A thickness of the third barrier layer 63 may be smaller than a thickness of the second barrier layer 62.

As an example, the third barrier layer 63 may include graphene oxide. The graphene oxide may be formed by a method such as spin coating. The graphene oxide may have semiconductor properties or insulating properties. The graphene oxide may have a greater thickness than the graphene. The thickness of the graphene oxide may be about 0.8 nm to about 1.2 nm.

As an example, the third barrier layer 63 may include reduced graphene oxide. The reduced graphene oxide may be formed by heating the graphene oxide by a thermal reduction method using a furnace to remove at least some of the functional groups. The reduced graphene oxide may have a smaller band gap than the graphene oxide. The reduced graphene oxide may have higher electrical conductivity and thermal conductivity than those of the graphene oxide. The reduced graphene oxide may have a greater thickness than the graphene, and may have a smaller thickness than the graphene oxide. The thickness of the reduced graphene oxide may be about 0.8 nm to about 1.2 nm.

Through this, a barrier structure B including at least one of the first barrier layer 61, the second barrier layer 62, and the third barrier layer 63 may be formed. For reference, the stacking order of the first barrier layer 61, the second barrier layer 62, and the third barrier layer 63 may be changed according to embodiments. The third barrier layer 63 may be formed on the first conductive layer 60, the second barrier layer 62 may be formed on the third barrier layer 63, and the first conductive layer 61 may be formed on the second barrier layer 62.

It is also possible to form the barrier structure B by alternately stacking at least two of the first barrier layers 61, the second barrier layers 62, and the third barrier layers 63. As an example, the barrier structure B may be formed by alternately stacking a plurality of second barrier layers 62 and a plurality of third barrier layers 63. In some embodiments, the barrier structure B may be formed by alternately stacking a plurality of second barrier layers 62 and a plurality of third barrier layers 63 over a single first barrier layer 61. As a result, when the first barrier layer 61 serves as a high-resistance layer to protect a memory cell from damage associated with a spike current, diffusion of an element from the first barrier layer 61 into the memory cell may be substantially prevented using the plurality of second barrier layers 62 and the plurality of third barrier layers 63. It is also possible to form the barrier structure B by alternately stacking barrier layers with a relatively high resistivity and barrier layers with a relatively low resistivity.

Referring to FIG. 6D, a first electrode layer 64 may be formed on the barrier structure B (or a first barrier structure). A variable resistance layer 65 may be formed on the first electrode layer 64. A second electrode layer 66 may be formed on the variable resistance layer 65. The first electrode layer 64, the variable resistance layer 65, and the second electrode layer 66 may be used to form a memory cell. In some embodiments, it is also possible to additionally form a second barrier structure on the second electrode layer 66. For example, the second barrier structure and the first barrier structure B may be formed to have a substantially symmetrical structure with respect to the memory cell.

Subsequently, a second conductive layer 67 may be formed on the second electrode layer 66. The second conductive layer 67 may be used to form an access line. As an example, the first conductive layer 60 may be used to form a word line, and the second conductive layer 67 may be used to form a bit line. Alternatively, the first conductive layer 60 may be used to form a bit line, and the second conductive layer 67 may be used to form a word line.

For reference, it is also possible to form the barrier structure B after forming the second electrode layer 66. In such a case, the second conductive layer 67 may be formed on the barrier structure B.

According to the manufacturing method described above, the barrier structure B may be formed between the access line and the electrode layer. The first barrier layer 61 may be the high-resistance barrier, and may reduce damage to the memory cell due to a spike current. The second barrier layer 62 may be the diffusion barrier, and may reduce diffusion of metal included in the first barrier layer 61 into the variable resistance layer 65. The third barrier layer 63 may be the amorphous barrier. The third barrier layer 63 may serve as a high-resistance barrier together with the first barrier layer 61 or serve as a diffusion barrier together with the second barrier layer 62.

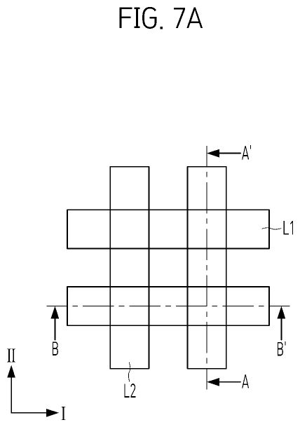

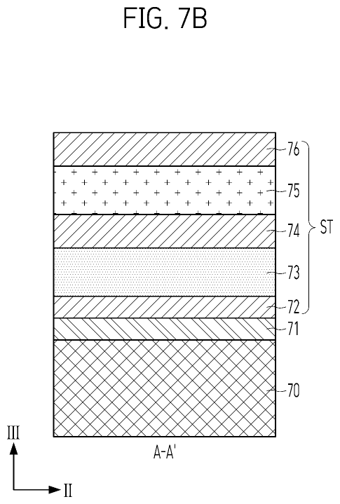

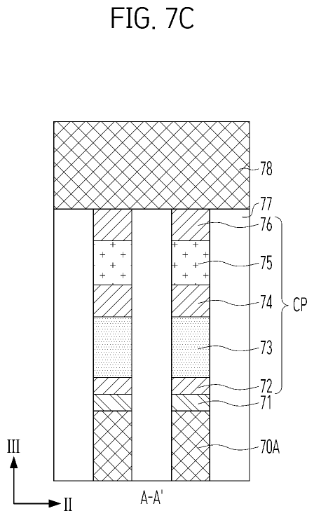

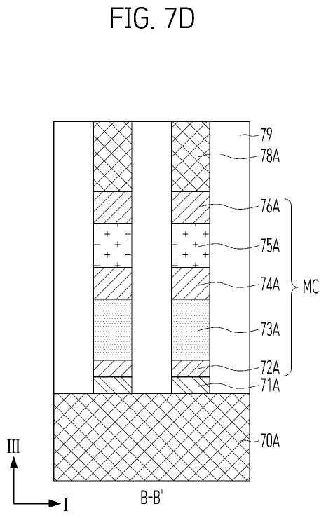

FIGS. 7A to 7D are diagrams for describing a manufacturing method of a semiconductor device in accordance with an embodiment. FIG. 7A is a plan view, FIGS. 7B and 7C are cross-sectional views taken along line A-A′ of FIG. 7A, and FIG. 7D is a cross-sectional view taken along line B-B′ of FIG. 7A. Hereinafter, the content overlapping with the previously described content will be omitted for the interest of brevity.

Referring to FIGS. 7A and 7B, a first conductive layer 70 may be formed. The first conductive layer 70 may be used to form a first access line.

Subsequently, a barrier structure (or an initial barrier structure) 71 may be formed on the first conductive layer 70. The barrier structure 71 may include at least one of a high-resistance barrier, a diffusion barrier, and an amorphous barrier. Subsequently, a stack ST may be formed on the barrier structure 71. The stack ST may include a first electrode layer (or an initial first electrode layer) 72, a switching layer (or an initial switching layer) 73, a second electrode layer (or an initial second electrode layer) 74, a variable resistance layer (or an initial variable resistance layer) 75, and a third electrode layer (or an initial third electrode layer) 76 or include a combination thereof. The stacking order of the layers included in the stack ST may be changed according to embodiments. For reference, it is also possible to additionally form a barrier structure on the stack ST.

Referring to FIGS. 7A and 7C, first access lines 70A and cell patterns CP may be formed. As an example, the cell patterns CP may be formed by etching the stack ST using a mask pattern as an etching barrier. The cell patterns CP may include first intermediate electrode layers 72, intermediate switching layers 73, intermediate second electrode layers 74, intermediate variable resistance layers 75, and intermediate third electrode layers 76. Barrier structures (or intermediate barrier structure) 71 in FIG. 7C may be formed by etching the initial barrier structure 71 in FIG. 7B. The first access lines 70A may be formed by etching the first conductive layer 70. The first access lines 70A, the barrier structures 71, and the cell patterns CP may extend in the first direction I. Subsequently, insulating layers 77 may be formed between the cell patterns CP, between the barrier structures 71, and between the first access lines 70A.

Subsequently, a second conductive layer 78 may be formed on the cell patterns CP and the insulating layers 77. The second conductive layer 78 may be used to form a second access line. For reference, it is also possible to additionally form a barrier structure before forming the second conductive layer 78.

Referring to FIGS. 7A and 7D, second access lines 78A extending in the second direction II intersecting the first direction I may be formed by etching the second conductive layer 78. Subsequently, memory cells MC may be formed by etching the cell patterns CP and the insulating layers 77. Each of the memory cells MC may include a first electrode 72A, a switching layer 73A, a second electrode 74A, a variable resistance layer 75A, and a third electrode 76A. The memory cells MC may be respectively located in regions where the first access lines 70A and the second access lines 78A intersect each other.

Subsequently, barrier structures 71A respectively located between the memory cells MC and the first access lines 70A may be formed by etching the barrier structures 71. The barrier structures 71A may be arranged in the first direction I and the second direction II. For reference, it is also possible to maintain a line shape of the barrier structures 71 without etching the barrier structures 71. Subsequently, insulating layers 79 may be formed between the memory cells MC, between the barrier structures 71A, and between the second access lines 78A.

According to the manufacturing method described above, the barrier structure 71A may be formed at one or both of a location between the memory cell MC and the first access line 70A and a location between the memory cell MC and the second access line 78A. Accordingly, the memory cell MC may be protected from diffusion of metal, a spike current, or the like.

Although embodiments according to the technical idea of the present disclosure have been described above with reference to the accompanying drawings, embodiments of the present disclosure are not limited to the above-described embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A semiconductor device comprising:
an access line;
a variable resistance layer;
an electrode located between the access line and the variable resistance layer; and
a barrier structure located between the access line and the electrode and including an amorphous barrier.

2. The semiconductor device of claim 1, wherein the barrier structure further includes a diffusion barrier, and the amorphous barrier has a resistivity higher than that of the diffusion barrier.

3. The semiconductor device of claim 2, wherein the diffusion barrier is located between the amorphous barrier and the access line.

4. The semiconductor device of claim 2, wherein the barrier structure further includes a resistance barrier located between the diffusion barrier and the access line, and the resistance barrier has a resistivity higher than that of the amorphous barrier.

5. The semiconductor device of claim 2, wherein the amorphous barrier is located between the diffusion barrier and the electrode.

6. The semiconductor device of claim 2, wherein the diffusion barrier includes metal nitride, and the amorphous barrier includes metal oxynitride.

7. The semiconductor device of claim 2, wherein the diffusion barrier includes graphene, and the amorphous barrier includes graphene oxide.

8. The semiconductor device of claim 2, wherein the diffusion barrier includes graphene, and the amorphous barrier includes reduced graphene oxide.

9. The semiconductor device of claim 1, wherein the amorphous barrier includes at least one of metal oxynitride, graphene oxide, and reduced graphene oxide.

10. The semiconductor device of claim 1, wherein the barrier structure includes a plurality of diffusion barriers and a plurality of amorphous barriers that are alternately stacked.

11. The semiconductor device of claim 1, wherein the barrier structure further includes a resistance barrier located between the amorphous barrier and the access line, and the resistance barrier has a resistivity higher than that of the amorphous barrier.

12. The semiconductor device of claim 11, wherein the resistance barrier includes a tungsten silicon nitride layer.

13. The semiconductor device of claim 11, wherein the barrier layer further includes a diffusion barrier located between the amorphous barrier and the resistance barrier.

14. A semiconductor device comprising:
a first access line;
a second access line intersecting the first access line;
a memory cell connected between the first access line and the second access line and including a variable resistance layer;
a crystalline barrier located between the memory cell and the first access line; and
an amorphous barrier located between the crystalline barrier and the memory cell.

15. The semiconductor device of claim 14, further comprising a resistance barrier located between the crystalline barrier and the first access line.

16. The semiconductor device of claim 15, wherein the resistance barrier includes a tungsten silicon nitride layer.

17. The semiconductor device of claim 14, wherein the amorphous barrier includes at least one of metal oxynitride, graphene oxide, and reduced graphene oxide.

18. The semiconductor device of claim 14, wherein the crystalline barrier includes at least one of metal nitride and graphene.

19. A manufacturing method of a semiconductor device, the manufacturing method comprising:
forming a first conductive layer;
forming a barrier structure on the first conductive layer, the barrier structure including an amorphous barrier;
forming a first electrode layer on the barrier structure; and
forming a variable resistance layer on the first electrode layer.

20. The manufacturing method of claim 19, wherein the forming of the barrier structure comprises:
forming a diffusion barrier on the first conductive layer; and
forming the amorphous barrier on the diffusion barrier.

21. The manufacturing method of claim 20, wherein in the forming of the amorphous barrier, a surface of the diffusion barrier is oxidized to form the amorphous barrier.

22. The manufacturing method of claim 19, wherein in the forming of the barrier structure, at least one diffusion barrier and at least one amorphous barrier are alternately stacked, the at least one amorphous barrier including the amorphous barrier.

23. The manufacturing method of claim 19, wherein the forming of the barrier structure comprises:
forming a metal nitride layer on the first conductive layer; and
forming a metal oxynitride layer by oxidizing the metal nitride layer.

24. The manufacturing method of claim 19, wherein the forming of the barrier structure comprises:
forming graphene on the first conductive layer; and
forming graphene oxide on the graphene.

25. The manufacturing method of claim 19, wherein the forming of the barrier structure comprises:
forming graphene on the first conductive layer; and
forming reduced graphene oxide on the graphene.

26. The manufacturing method of claim 19, wherein the forming of the barrier structure comprises:
forming a resistance barrier on the first conductive layer; and
forming the amorphous barrier on the resistance barrier.

27. The manufacturing method of claim 19, wherein the forming of the barrier structure comprises:
forming a resistance barrier on the first conductive layer;
forming a diffusion barrier on the resistance barrier; and
forming the amorphous barrier on the diffusion barrier.

28. The manufacturing method of claim 27, wherein the resistance barrier includes a tungsten silicon nitride layer.

29. The manufacturing method of claim 27, wherein the diffusion barrier includes metal nitride, and the amorphous barrier includes metal oxynitride.

30. The manufacturing method of claim 27, wherein the diffusion barrier includes graphene, and the amorphous barrier includes graphene oxide.

31. The manufacturing method of claim 27, wherein the diffusion barrier includes graphene, and the amorphous barrier includes reduced graphene oxide.

32. The manufacturing method of claim 19, further comprising:
forming a second electrode layer on the variable resistance layer; and
forming a second conductive layer on the second electrode layer.
